(19) United States
(12) Patent Application Publication
(10) Pub. No.: US 2020/0035385 A1
(43) Pub. Date: Jan. 30, 2020

(54) HEATING AND/OR COOLING DEVICE FOR A SOLID OR FOR A FLUID STREAM

(71) Applicant: GEBR. KRALLMANN GMBH, Hiddenhausen (DE)

(72) Inventor: Ingo BREXELER, Wetter/Ruhr (DE)

(21) Appl. No.: 16/484,359

(22) PCT Filed: Feb. 7, 2018
(86) PCT No.: PCT/EP2018/000052

§ 371 Date: Aug. 7, 2019

(30) Foreign Application Priority Data
Feb. 8, 2017 (DE) 10 2017 001 461.2

(51) Int. Cl. H01C 1/14; H01C 1/012; H01C 1/028; H01C 7/02; H05B 3/26; H05K 7/20

(52) U.S. Cl. CPC H01C 1/1406; H01C 1/012; H01C 1/028; H05B 2203/02; H05B 3/26; H05K 7/20; H01C 7/02

(57) ABSTRACT

A heating and/or cooling device for a solid or for a fluid stream includes a carrier part formed of plastic, in which an electrical heating and/or cooling element is embedded and held. A metallic distributor element is in contact with the heating and/or cooling element. At least one terminal contact and an electrical strip conductor, which connects the terminal contact to the heating and/or cooling element, are provided. The heating and/or cooling element are prefabricated and are connected to the carrier part formed of plastic by an injection molding process. Electrical strip conductors are prepared for connecting the heating and cooling element by a metal injection molding process or metal casting process.

### CROSS REFERENCE TO RELATED APPLICATIONS

This application is a United States National Phase Application of International Application PCT/EP2018/000052 filed Feb. 7, 2018, and claims the benefit of priority under 35 U.S.C. § 119 of German Application 10 2017 001 461.2, filed Feb. 8, 2017, the entire contents of which are incorporated herein by reference.

### TECHNICAL FIELD

The present invention pertains to a heating and/or cooling device for a solid or for a fluid stream and to a process for manufacturing a corresponding heating and/or cooling device.

The present invention further pertains to a tool handle with a corresponding heating and/or cooling device, to a camera housing and/or camera handle with a corresponding heating and/or cooling device and to a motor vehicle exhaust gas device, into which a corresponding heating and/or cooling device is integrated.

### TECHNICAL BACKGROUND

It is necessary in many fields of industry to regulate the temperature of, i.e., to heat or cool, gas mixtures, liquids or even solids in a very limited space. The heating of a solid will be used as an example below, but the present invention is not limited to this.

A corresponding solid may be, for example, a heatable handle of a tool, e.g., of a power saw, or of a camera, or a camera housing. The heating of the handle or of the housing is usually employed to make the handling of the tool or of the camera more comfortable for a user during use outside buildings and especially outdoors in the winter. A heating device, which comprises a thin-walled plate made of stainless steel, is known for this purpose. A prefabricated heating element, especially a so-called PTC resistor or PTC thermistor (Positive Temperature Coefficient Thermistor), is arranged on the outer surface of the plate. This is a temperature-dependent resistor, which conducts the electric current better at low temperatures than at high temperatures. The heating element is fastened and especially soldered to the outer side of the plate. This intermediate product thus formed is then inserted into a plastic injection molding device and extrusion-coated with a plastic jacket, as a result of which the heating element is positioned securely in relation to the tubular plate. This procedure requires a plurality of different process steps and is thus very complicated and costly.

According to another application example, a corresponding heating device is used in the automobile industry. It is known, especially in diesel engines, that a urea-water solution is introduced into the exhaust gas stream in front of the catalytic converter for the exhaust gas treatment or for reducing the nitrogen oxide levels. At relatively low outside temperatures, it is necessary for this to maintain the urea-water solution at a desired operating temperature by heating. Moreover, the solution must be heated and thawed at low outside temperatures during the idle state of the vehicle. A heating device used for this purpose has a thin-walled jacket, to which a PTC resistor or PTC thermistor is fastened. This intermediate product is extrusion-coated in a plastic injection molding device in the aforementioned manner. This procedure is very complicated as well.

### SUMMARY

A basic object of the present invention is to provide a heating and/or cooling device of the above-mentioned type, which can be manufactured in a simpler or more cost-effective manner.

Moreover, a process for manufacturing a corresponding heating and/or cooling device, which can be carried out in a simple and cost-effective manner, shall be provided.

The present invention is based on the basic idea of building the heating and/or cooling device from a prefabricated heating and/or cooling element, for example, a PTC thermistor or a Peltier element, and of connecting the heating and/or cooling element with an injection-molded carrier part consisting of plastic, and of also forming the electrical terminals as well as a metallic distributor element, which is used to distribute heat or cold over a predefined surface area, by means of metal injection molding or metal casting.

The heating and/or cooling device according to the present invention for a solid or for a fluid stream has a carrier part consisting of plastic, which may be a carrier plate or also a tubular carrier part. The prefabricated electrical heating and/or cooling element is held and especially embedded in the carrier part. The metallic distributor element, which may be injected, for example, in advance or later, is in contact with the heating and/or cooling element. In particular, at least one terminal contact and especially at least two terminal contacts are provided, via which an external electrical voltage source can be connected. The terminal contacts may be prefabricated components, which are inserted into the injection molding device, but it is also possible, as an alternative, to likewise form the terminal contacts by means of the metal injection molding or metal casting process. In addition, an electrical strip conductor is provided, which connects one of the terminal contacts to the heating and cooling element. The other terminal contact may be connected to the heating and/or cooling element via the metallic distributor element.

Provisions are made in a preferred embodiment of the present invention for the heating and/or cooling element to be held in the carrier part consisting of plastic at least in a positive-locking manner. In addition or as an alternative to the positive-locking holding, a non-positive holding may be present, for example, via an adhesive force or a bonding force.

The metallic distributor element may be, for example, a flat plate or a curved plate or even a tube element. However, other geometries are conceivable as well.

To guarantee a secure, durable contact between the cooling and/or heating element and the distributor element, so that good heat transmission and also a flow of electrical current will occur between these components, provisions may be made in a variant of the present invention for the metallic distributor element to be permanently connected and especially soldered to the heating and/or cooling element. The permanent connection and especially the soldered connection is formed directly during the introduction of the metal melt, without additional working steps being necessary for the connection. The surface of the heating and/or cooling element, which surface is to be connected to the metal melt, is preferably pretreated. This may be a plasma pretreatment and/or the application of a contact agent or of a flux.

The metallic distributor element preferably consists of an injectable metal melt and especially a low-alloy metal melt, which may be, for example, an electronic solder used in electronics. A soft solder in the form of a tin alloy is usually used as an electronic solder.

Provisions may be made in a possible embodiment of the present invention for the metallic distributor element to be embedded or inserted into a recess formed in the carrier part.

The distributor element is preferably held at least in a positive-locking manner at the carrier plate. As an alternative or in addition to this, provisions may, however, also be made for the distributor element to be held at the carrier plate in a non-positive manner, for example, by means of an adhesive force or by means of a bonding force.

The strip conductor, which connects one of the terminal contacts to the heating and/or cooling element, is preferably prepared by metal injection molding or metal casting and may be formed for this purpose from a low-alloy metal melt, especially an electronic solder. A soft solder in the form of a tin alloy is usually used as the electronic solder.

The strip conductor is preferably embedded into a recess or groove formed in the carrier part and can be held in this in a positive-locking and/or non-positive manner.

To guarantee a secure, durable contact between the cooling and/or heating element and the strip conductor, so that good heat transmission and also good flow of electrical current between these components will occur, provisions may be made in a variant of the present invention for the strip conductor to be permanently connected and especially soldered to the heating and/or cooling element. The permanent connection and especially the soldered connection is formed immediately during the introduction of the metal melt, without additional working steps being necessary for this. The surface of the heating and/or cooling element, which surface is to be connected to the metal melt, is preferably pretreated. This may be a plasma pretreatment and/or the application of a contact agent or of a flux.

Provisions may be made in a variant of the present invention for the strip conductor to be provided at its end arranged at the heating and/or cooling element with a contact part made integrally in one piece with it, which is preferably adapted to the dimensions of the heating and/or cooling element, so that a good electrical connection is ensured between the strip conductor and the heating and/or cooling element.

In a possible application of said heating and/or cooling device, the latter is integrated in the handle of a tool, especially of a motor-driven tool, for example, a power saw, or in the handle or the housing of a camera. Reference is made to the above explanations concerning the configuration of the heating and/or cooling device integrated in the handle or in the housing.

Furthermore, a motor vehicle exhaust gas device may be provided, which has a flow duct, in which the exhaust gas of, for example, a diesel engine or a liquid flows. In order to maintain the exhaust gas or the liquid at a predefined temperature or to bring to that temperature, a heating and/or cooling device of the type mentioned may be integrated in the flow duct.

Various procedures are conceivable for manufacturing said heating and/or cooling device:

In a first possible embodiment of the process according to the present invention, provisions may be made for manufacturing first a carrier part consisting of plastic in an injection molding device. The carrier part may be, for example, a plate, a block or a tube element.

A prefabricated heating and/or cooling element (PTC thermistor or Peltier element) is then arranged at or in the carrier element. Corresponding recesses, depressions or other positioning aids may be formed in the carrier part for the accurate positioning of the heating and/or cooling element.

A liquid metal, for example, electronic solder, is then applied in a metal injection molding or metal casting process, as a result of which at least one and preferably a plurality of strip conductors formed from the metal melt and/or at least one metallic distributor element are formed at the carrier part and are connected each to the heating and/or carrier element. Depressions or grooves, into which the metal melt is introduced to form the strip conductors and the distributor element, are preferably formed in the carrier part.

The strip conductors are used to make it possible to connect the heating and/or cooling element to an external electrical voltage source preferably via contact parts that are either prefabricated or are likewise formed according to the metal injection molding or metal casting process.

The distributor element is used, for example, to distribute the heat generated by the heating and/or cooling element over a larger surface area and thus to form a larger contact surface for the heating and/or cooling device with the fluid to be heated or to be cooled.

An outer protective jacket consisting of plastic may be applied by injection molding in a subsequent process step in order to protect the metallic components from external effects and to insulate these electrically. The protective jacket may be dimensioned and shaped such that it forms the component to be heated and/or to be cooled, for example, a handle.

Provisions may be made in an alternative embodiment of the present invention for a prefabricated heating and/or cooling element (PTC thermistor or Peltier element) to be arranged first in a plastic injection molding device and to be extrusion-coated with plastic in this device, while forming a carrier such that the heating and/or cooling element is arranged and held at or in the carrier part. The metal injection molding or metal casting process is then carried out in the above-described embodiment to form the strip conductor and/or the distributor element and/or the terminal contacts, and a protective jacket consisting of plastic is finally applied by injection. The protective jacket may be dimensioned and shaped such that it forms the component to be heated and/or cooled, for example, a handle.

In another alternative embodiment of the process, the carrier part consisting of plastic is likewise manufactured first in the manner described. However, instead of arranging first the prefabricated heating and/or cooling element at the carrier part, said metal injection molding or metal casting process is carried out first to form the strip conductor and/or the distributor element and/or the terminal contacts, after which the prefabricated heating and/or cooling element is arranged at the carrier part and is electrically connected to the distributor element. A protective jacket consisting of plastic may subsequently be applied by injection in the manner described. The protective jacket may be dimensioned and shaped such that it forms the component to be heated and/or cooled, for example, a handle.

Provisions are made in a preferred embodiment of the present invention for the heating and/or cooling element to be subjected to a plasma treatment prior to the introduction of the metal melt. This plasma treatment may be carried out especially within the closed injection mold.

In addition or as an alternative hereto, provisions may be made for a contact agent or a flux to be applied to the heating and/or cooling element prior to the introduction of the metal melt.

As an alternative or in addition hereto, a permanent connection can be achieved between the heating and/or cooling element and the electrically conducting and heat-conducting components connected thereto, i.e., the strip conductor and/or the distributor element by the components being connected by means of an electrically conducting and heat-conducting adhesive.

Further details and features of the present invention can be seen in the following description of an exemplary embodiment with reference to the drawings.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 is a perspective top view of a heating and/or cooling device according to the present invention;

FIG. 2 is a perspective bottom view of the heating and/or cooling device according to FIG. 1;

FIG. 3 is a perspective exploded view of the components of the heating and/or cooling device;

FIG. 4 is a perspective sectional view of the heating and/or cooling device according to FIG. 1; and

FIG. 5 is an enlarged detail view showing detail V in FIG. 4.

### DESCRIPTION OF PREFERRED EMBODIMENTS

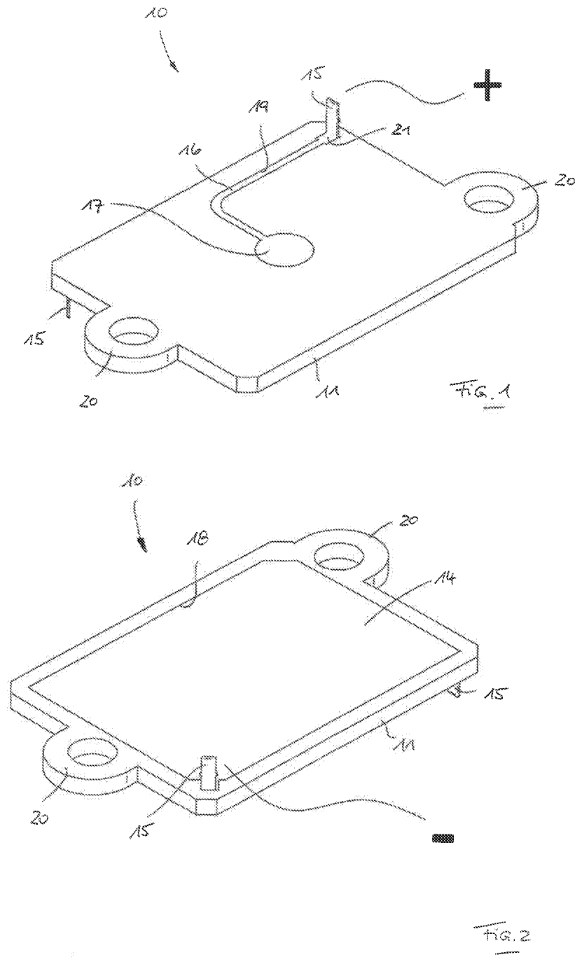

Referring to the drawings, a heating and/or cooling device 10 for a fluid stream, which device is shown in FIGS. 1 through 5, has a plate-shaped carrier part 11 consisting of plastic, in which carrier part 11 a large-surface recess 18, a perforation 12 and a groove-shaped recess 19 are formed, the recess 18 and the groove-shaped recess 19 being arranged on opposite sides of the carrier part 11.

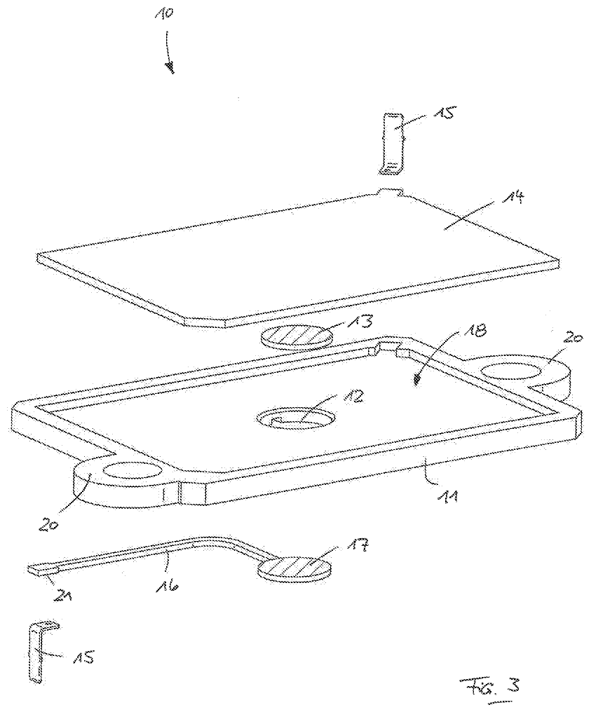

A prefabricated terminal contact 15 is arranged in a corner area each on the top side of the carrier part 11 as well as on the opposite bottom side of the carrier part 11. The one terminal contact 15 may be connected to a positive pole of an electrical voltage source (see sign “+” in FIG. 1), while the other terminal contact 15 may be connected to a negative pole of the electrical voltage source (see sign “−” in FIG. 2).

Fastening lugs 20, which make it possible to fasten the heating and/or cooling device 10 at the desired location of use, for example, in a vehicle, are made integrally in one piece with the carrier part 11.

A prefabricated heating and/or cooling element 13, which may be a PTC thermistor or a Peltier element, is inserted into the perforation 12. In the exemplary embodiment shown, the heating and/or cooling element 13 has the shape of a flat circular disk and the perforation 12 is configured correspondingly with a circular cross section. The dimensions of the heating and/or cooling element 13 and of the perforation 12 are coordinated with one another such that the heating and/or cooling element 13 is positioned securely in the perforation 12.

A groove-like or channel-like recess 19, which extends between the terminal contact 15 arranged on the top side of the carrier part 11 and the perforation 12 and connects these two components to one another, is formed on the top side of the carrier part 11 (see FIG. 1). A strip conductor 16, which is formed from a metal melt, is introduced and especially injected or poured into the recess 19. At its end facing the perforation 12, the strip conductor 16 has a contact part 17 of enlarged dimensions. The contact part 17 is adapted in the exemplary embodiment shown to the dimensions of the perforations 12 and of the heating and/or cooling element 13 and is thus likewise configured as a flat circular disk, as it is shown in FIG. 3.

A contact part 21 with increased dimensions, via which the strip conductor 16 is in electrically conducting connection with the terminal contact 15, is also formed at the end of the strip conductor 16 that faces away from the contact part 17 and faces the terminal contact 15.

A metallic, plate-shaped distributor element 14 is inserted with close fit it into the large-surface recess 18 on the underside of the plate-shaped carrier part 11. The distributor element 14 may be prefabricated, but it is preferably formed by injecting or casting in a metal melt and it is in electrically conducting contact with the terminal element 15 arranged in the corner area and it contacts the heating and/or cooling element 13, so that there is an electrically conducting contact with this as well. The distributor element 14 is used, for example, to distribute the heat generated by the heating and/or cooling element 13 to a large-surface area.

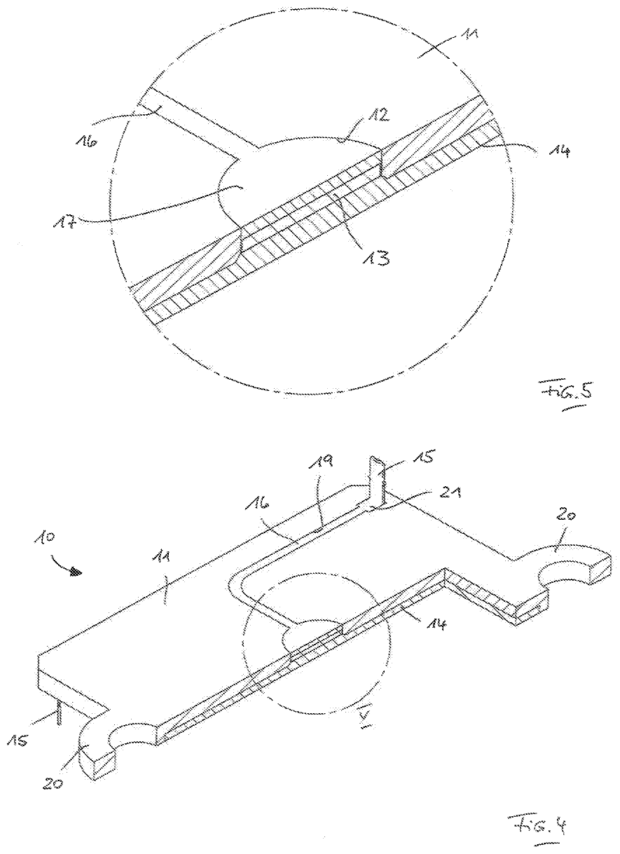

FIGS. 4 and 5 show that the heating and/or cooling element 13 is arranged between the plate-shaped distributor element 14 and the contact part 17 of the strip conductor 16 with close fit.

If the heating and/or cooling device 10 is connected via the two terminal contacts 15 to an electrical voltage source, the heating and/or cooling element 13 are arranged in the electrical circuit via the strip conductor 16 and the distributor element 14. If the heating and/or cooling element 13 is a PCT thermistor, it represents a resistor, at which heat is generated. This heat is released to the plate-shaped distributor element 14 and is distributed over a large-surface area. The distributor element 14 is used as a heat exchanger for a fluid flowing past the heating and/or cooling device 10 and especially past the distributor element 14, as a result which this element is heated.

While specific embodiments of the invention have been shown and described in detail to illustrate the application of the principles of the invention, it will be understood that the invention may be embodied otherwise without departing from such principles.

1. A heating and/or cooling device for a solid and/or for a fluid stream, the device comprising:
an electrical heating and/or cooling element;
a carrier part formed of plastic and at which the electrical heating and/or cooling element is held;
a metallic distributor element that is in contact with the heating and/or cooling element;
at least one terminal contact; and
an electrical strip conductor, which connects the terminal contact to the heating and/or cooling element.

2. A heating and/or cooling device in accordance with claim 1, wherein a PTC resistor or PTC thermistor is provided as the heating clement.

3. A heating and/or cooling device in accordance with claim 1, wherein a Peltier clement is provided as a heating and/or cooling element.

4. A heating and/or cooling device in accordance with claim 1, wherein the heating and/or cooling element is embedded in the carrier part.

5. A heating and/or cooling device in accordance with claim 1, wherein the heating and/or cooling element is positive lockingly held in the carrier part.

6. A heating and/or cooling device in accordance with claim 1, wherein the metallic distributor element is formed from a low-alloy metal melt.

7. A heating and/or cooling device in accordance with claim 1, wherein the metallic distributor element is embedded in a recess formed in the carrier part.

8. A heating and/or cooling device in accordance with claim 1, wherein the metallic distributor element is formed by a flat or curved plate or by a tube element.

9. A heating and/or cooling device in accordance with claim 1, wherein the distributor element is held at the carrier plate at least in a positive-locking manner.

10. A heating and/or cooling device in accordance with claim 1, wherein the metallic distributor element is permanently connected to the heating and/or cooling element.

11. A heating and/or cooling device in accordance with claim 10, wherein the metallic distributor element is soldered to the heating and/or cooling element.

12. A heating and/or cooling device in accordance with claim 1, wherein the strip conductor is formed from a low-alloy metal melt.

13. A heating and/or cooling device in accordance with claim 1, wherein the strip conductor is embedded in a recess or groove formed in the carrier part.

14. A heating and/or cooling device in accordance with claim 1, wherein the strip conductor is permanently connected to the heating and/or cooling element.

15. A heating and/or cooling device in accordance with claim 14, wherein the strip conductor is soldered to the heating and/or cooling element.

16. A heating and/or cooling device in accordance with claim 1, wherein the strip conductor is provided with a contact part made integrally in one piece at its end arranged at the heating and/or cooling element.

17. A heating and/or cooling device in accordance with claim 1, wherein at least two terminal contacts are provided, by means of which the heating and/or cooling clement can be connected to an external electrical voltage source.

18. A heating and/or cooling device according to claim 1, in combination with a tool handle with the heating and/or cooling device integrated in the tool handle.

19. A heating and/or cooling device according to claim 1, in combination with a camera handle with the heating and/or cooling device integrated in the handle.

20. A heating and/or cooling device according to claim 1, in combination with a camera housing with the heating and/or cooling device integrated in the housing.

21. A heating and/or cooling device according to claim 1, in combination with a motor vehicle exhaust gas device with a flow duct, in which the heating and/or cooling device is integrated.

22. A process for manufacturing a heating and/or cooling device, the process comprising the steps of:
forming a carrier part of plastic in an injection molding device;
subsequent to said step of forming, arranging a prefabricated heating and/or cooling element at or in the carrier part;
subsequent to said step of arranging, forming at least one strip conductor from a metal melt at the carrier part and/or forming at least one metallic distributor element at the carrier part in a metal injection molding process or metal casting process and arc connected to the heating and/or cooling element, whereby the heating and/or cooling device is provided comprising the electrical heating and/or cooling element, the carrier part holding the electrical heating and/or cooling element, the distributor element in contact with the heating and/or cooling element at least one terminal contact and the electrical strip conductor, connecting the terminal contact to the heating and/or cooling element.

23. A process for manufacturing a healing and/or cooling device, the process comprising the steps of:
arranging a prefabricated heating and/or cooling element in an injection molding device
extrusion-coating the arranged prefabricated heating and/or cooling element with plastic, while forming a carrier part, such that the prefabricated healing and/or cooling element is arranged and held at or in the carrier part; and
subsequent to said step of extrusion-coating, forming at least one strip conductor from a metal melt and/or forming at least one metallic distributor element from a metal melt at the carrier part in a metal injection molding process or metal casting process and arc connected to the heating and/or cooling element, whereby the heating and/or cooling device is provided comprising the electrical heating and/or cooling element, the carrier part holding the electrical heating and/or cooling element, the distributor element in contact with the heating and/or cooling element at least one terminal contact and the electrical strip conductor, connecting the terminal contact to the heating and/or cooling element.

24. A process for manufacturing a heating and/or cooling device, the process comprising the steps of:
forming a carrier part of plastic in an injection molding device;
subsequent to said step of forming the carrier part, forming at least one strip conductor from a metal melt and/or forming at least one metallic distributor element at or in the carrier part in a metal injection molding process or metal casting process and wherein
subsequent to said injection molding process or metal casting process, applying a prefabricated heating and/or cooling element to the carrier part and is connected to the strip conductor and/or to the distributor element, whereby the heating and/or cooling device is provided comprising the electrical heating and/or cooling element, the carrier part holding the electrical heating and/or cooling element, the distributor element in contact with the healing and/or cooling element at least one terminal contact and the electrical strip conductor, connecting the terminal contact to the heating and/or cooling element.

25. A process in accordance with claim 21, wherein a protective jacket consisting of plastic is applied by spraying in a subsequent process step.

26. A process in accordance with claim 21, wherein the heating and/or cooling element is subjected to a plasma treatment prior to the introduction of the metal melt.

27. A process in accordance with claim 21, wherein a contact agent or a flux is applied to the heating and/or cooling element prior to the introduction of the metal melt.
